(19) United States
(12) Patent Application Publication
(10) Pub. No.: US 2026/0290760 A1
(43) Pub. Date: Sep. 24, 2026

(54) IMPROVED PLASMA PRODUCTS AND METHODS FOR PRODUCING SAME BY USING MULTIPLE SIMULTANEOUS ELECTRICAL DISCHARGES

(71) Applicant: PLAZER IP, LLC, De Pere, WI (US)

(72) Inventors: David Garman, Lindfield (AU); Ihor Medvediev, De Pere, WI (US); Oleksandr Harnyi, Kyiv (UA)

(73) Assignee: PLAZER IP, LLC, De Pere, WI (US)

(21) Appl. No.: 19/106,109

(22) PCT Filed: Aug. 25, 2023
(86) PCT No.: PCT/US23/31155

§ 371 Date: Feb. 24, 2025

Related U.S. Application Data
(60) Provisional application No. 63/401,473, filed on Aug. 26, 2022.
(60) Provisional application No. 63/451,080, filed on Mar. 9, 2023.

(51) Int. Cl. H01J 37/32; C04B 7/44

(52) U.S. Cl. CPC H01J 37/32568; C04B 7/4453; H01J 37/321; H01J 37/32174; H01J 37/32743; H01J 2237/204; H01J 2237/24585

(57) ABSTRACT

Improved plasma products are produced using a non-thermal plasma reaction chamber with freely moving electrode segments disposed within the chamber. Input materials may be solids, liquids, gases or combinations thereof depending on the type of improved plasma product desired or required. Control of plasma intensity and residual free radicals are monitored on-line to control changes in frequency, magnetic field and number of electrode segments which allow for control of plasma intensity and residual free radicals. This results in a myriad of synergistic reactions of the input materials within the reaction chamber to produce the improved plasma product at an output. The improved plasma products have properties that are superior to like products that are not so treated. Electrode materials can be varied to catalyze the intended reaction. Electrode segment size and composition can also be varied to adjust for the desired, required or intended result or outcome.

This application claims the benefit of United States. Provisional Patent Application Nos. 63/401,473 filed Aug. 26, 2022 and 63/451,080 filed Mar. 9, 2023.

### FIELD OF THE INVENTION

The present invention relates generally to non-thermal plasma production, plasma processing and combined plasma producing and processing systems. It also relates generally to non-thermal plasma producing and processing systems of the type having a plasma producing and processing chamber through which water, liquids, gases, combined water and liquid borne solids, and the like, can pass and be treated. More specifically, the present invention relates to a system and method for producing multiple simultaneous electrical discharges for up to an indefinite period of time to form a wide variety of improved plasma products that are able to be maintained at a certain quality, rate, or level over a useful lifetime resulting in continuous and commercially viable throughputs, all being done at rates of milliseconds or even smaller time intervals; with the production of solid particle size reductions from millimeter to micron size and from micron size to nanometer size; and with the ability to create long-lived sustainable reactive reagents that are processed within and discharged from the plasma producing and processing chamber. One particular application relates to using the method and process of the present invention to improve the properties of cements, concretes and mortars, and the resultant mixtures after the addition of water and other materials. The material strengths obtained by this method are multiples in strength superior to those of conventional mixing methods. Other applications will be apparent from the detailed description provided.

### BACKGROUND OF THE INVENTION

All matter is comprised of atoms which are composed of a nucleus and electrons. The nucleus is composed of protons and neutrons. Around the nucleus are the electrons. Further, all matter is also known to exist in at least one of four states-solid, liquid, gas or plasma. Solids have the lowest molecular energy and have molecular constructs that are arranged in a regular, repeating pattern with only vibrational movement at the molecular level. Solids have a definite shape and a definite volume. However, liquids have a definite volume but an indefinite shape. Liquids have limited attractive forces between the molecules that allow them to flow past one another. Atoms and molecules (neutral substances) in gaseous state gain enough energy to break free of the attractive forces between them. In this state, gases have an indefinite shape and an indefinite volume. Plasma is formed as the energy increases in gaseous atoms to the point of stripping electrons from the neutral gases, whereby the resultant energy-charged gas becomes a plasma.

As is deduced from the foregoing, a matter or substance in any one of these states generally can be changed from one state to another by adding energy to the substance or by removing energy from the substance. Such energy is typically provided in the form of thermal or electrical energy. The amount of energy required for changing a solid to a liquid and a liquid to a gas is relatively small. A basic example of this is water, or H₂O. By adding still more thermal energy to ice (water in its solid state), the solid state of water is changed to a liquid. Adding even more heat energy to the liquid state changes it to a gaseous state (however, note that the white vapor often referred to as “steam” is, in reality, the gaseous state of water that is starting to change back to its liquid state).

However, changing the state of water to a plasma requires a tremendous amount of heat energy or non-thermal electrical energy, either of which can turn water into a hydrogen and oxygen plasma. That is, water is a molecule and water, in its plasma state, exists as a reduced combination of H+ and OH− ions. Water is a limited example because once this ionization takes place, the ions are not revertible back to water in its gaseous state. Where this ionization is created by electrical energy, this “electrically expanded water” is water that has soaked up a substantial amount of electricity-far more than that required to change ice to water and water to gaseous state. This, in turn, provides for a generous amount of internal energy. This effect is not unique to water. In other applications, and with other substances, plasma may consist of ions, electrons, neutral molecules, excited molecules and ultraviolet light (“UV”).

Highly ionized plasmas have many applications. By being capable of containing enough energy to change the atomic structures of substances, plasma can destroy contaminants and toxic waste. Plasma can also be used for cleaning particulates, eliminating particulates, changing particle size, enhancing the adhesion of surfaces, activating surfaces, modifying the surfaces of organic and inorganic materials, producing free radicals (including UV, stabilized in a magnetic field, free electrons, pressure, and cavitation waves), oxidizing complex materials using free radicals, depositing thin coatings, and forming and breaking down new chemical compounds and mixtures. Plasma cleaning can reduce and even eliminate surface contaminants such as oils and grease. The presence of UV in plasma breaks down the organic bonds of contaminants. Plasma surface modification and activation can enhance adherence of surface coatings and bonding materials. Such activation can last for substantial periods of time depending on the type of material being activated. Plasma coating can be used for laying down layers of conductive material in the creation of certain electronic components, such as electronic mask works.

Relative to the surface cleaning of substances as referenced above, plasma cleaning can be accomplished in many nanoscale applications as well. By using inert gases such as argon and helium, easily oxidized metals can be cleaned by vaporizing and removing organic contaminants which can then be discharged from the plasma chamber. Surface activation and coatings can also be accomplished at this nanoscale level as discussed infra.

One limitation in the prior art of plasma producing and processing chambers (or “plasma chamber” for brevity) is the inadequacy of scale. That is, most work in this art has been done with single or small numbers of electrodes that create individual discharges that may or not interact. The plasma chambers are relatively small and reaction times are slow, so use of this technology to date tends to be limited to single materials having relatively small throughputs. The prior art is simply not configured to enable any large commercial application of the reaction or to sustain the reaction for an extended period of time as is desired or required for a given application or treatment time.

Another limitation in the prior art of plasma chambers is the ability of such chambers to be used for an extremely wide variety of treatment options. That is, plasma chambers of the prior art are limited in the way that plasma reactions can create improved plasma products that are able to be maintained at a certain quality, rate, or level over a useful lifetime, which is the most significant limitation of the prior art that needs to be overcome in order to realize commercially viable plasma products.

### SUMMARY OF THE INVENTION

The present invention provides improved plasma products, which is so much more than typical product surface modification. This summary gives an overview of the wide range of diverse plasma generation methods and plasma sources that can be realized in accordance with the present invention—each of which is novel in the art.

One embodiment of the present invention highlights the broad spectrum of plasma product properties which, in turn, lead to a wide range of diverse technological applications. The present invention is capable of processing larger volumes, the prior art having been effectively restricted to (a) small volumes (as the prior art demonstrates use of small flow rates as well, i.e., less than 1 cubic meter per hour with the reaction time for complex molecules going up to 2 hours); (b) single materials; and (c) smaller throughputs (again, less than 1 cubic meter per hour). It should be noted that smaller volume outputs could be realized where the throughput and output from the plasma chamber is being performed on a continuous basis, which the present invention is capable of.

Relative to the shortcomings of the prior art referenced immediately above, these inventors are realizing reaction times as low as 1 second, but as long as 10 seconds; using plasma with complex materials, rather than single materials; and throughputs that start at 5 cubic meters per hour up to 50 cubic meters per hour (although, under some circumstances, this could go as high as two or three times that). These inventors will demonstrate that they can do all of these things, which have not yet been done or have not been demonstrated at medium to large volume in the prior art.

The terms “input”, “throughput” and “output” relative to the creation of improved plasma products in accordance with the present invention and in relation to the use of a plasma chamber shall have their ordinary meaning. That is, input material is material put into the plasma chamber. Throughput material is material that is actively passing through the plasma chamber. Output material is material that comes out of the plasma chamber.

By way of a first example in this particular regard, the inventors note that the United States Environmental Protection Agency (“EPA”) has begun to impose mandatory standards for the elimination of poly- and perfluoroalkyl substances (“PFAS”) from municipal drinking water. PFAS are a large family of over 12,000 highly persistent and toxic chemicals that do not occur in nature and are colloquially known as the “Forever Chemicals”. These inventors note the following regarding this subject:
Current physical methods for PFAS remediation include GAC, IX, reverse osmosis and nanofiltration; although effective, they produce residuals that require disposal or further treatment. Advanced oxidation processes, such as ultraviolet light or ozone with peroxide, are ineffective in PFAS treatment because of the high stability of the carbon-fluorine bond comprising these compounds. Consequently, reductive and thermal technologies such as electrochemical, radiolytic, sonochemical, and photocatalytic methods including pyrolysis, gasification, supercritical water oxidation, and plasma processing have been evaluated for PFOA and PFOS degradation. While effective, many of these technologies are impractical for large-scale treatment given their long treatment times (hours), low treatment volumes, or prohibitively high energy requirements (emphasis added).
   Source: Selma Mededovic Thagard, Focusing water treatment efforts on the destruction of poly- and perfluoroalkyl substances (PFAS): the United States perspective, 24 Clean Technologies and Environmental Policy 1619-20 (2022)

However, these inventors also recognize that simple scalability could be regarded as something that is obvious to a person having ordinary skill in the art. What is not obvious is the method and mechanism by which plasma reactions can create improved plasma products that are able to be maintained at a certain quality, rate, or level over a useful lifetime and methods for producing such plasma products by using multiple simultaneous electrical discharges. There are several aspects of the present invention that are of particular relevance in this last regard.

One is the use of multiple detached, discrete and randomly disposed linear electrode segments that are freely moving within a plasma chamber (as opposed to being fixed or stationary) to form an improved plasma product during the reaction phase and to create synergistic reactions that result in the formation of such improved plasma products, which products have superior properties as compared to the same products being formed without use of the plasma chamber as described herein.

Another is the use of a variety of electrode segment material(s) (i.e., the material or materials the electrode segments are made of) that can catalyze reactions, each variant providing a different catalytic reaction. Fabricating such electrode segments can involve specific structural and chemical composition alterations (e.g., the general use of inert tips on opposing ends of such structures, the use of gold tips, the complete encapsulation of such structures with electrically conductive material, etc.) of the type that can greatly impact the catalyzation reaction created within the plasma chamber that the electrodes are used with.

Still another is the liner within which the electrode segments are contained, i.e., the liner being configured to be part of the plasma chamber, which is a type of “reactor”. The material from which the liners are or can be fabricated also acts as a catalyst within the synergistic reactions that form improved plasma products that are able to be maintained at a certain quality, rate, or level over a useful lifetime.

None of the foregoing aspects is obvious in view of what is fairly taught by the prior art. That is, electrode segment size and composition (including surface composition) can be varied, as can liner material, to adjust for a desired, required or intended result, all in accordance with the present invention. Further, the present invention can be applied using solids, liquids, liquids carrying solids, and gases under different configurations. By way of another example, these inventors are aware that useful plasma formation has not previously been demonstrated except for discharges in air-such as ozone formation and this is very inefficient with only 15% conversion and with thermal plasmas, but not for non-thermal and/or plasma in liquid discharges.

A further advantage that is not recognized in prior art is that the energy required to maintain and propagate plasma reactions in accordance with the present invention is lower than many conventional non-plasma reactions and comparable to or lower than the most efficient treatment options.

The foregoing and other features of the improved plasma products and processes for producing same in accordance with the present invention will be apparent from the detailed description that follows.

### BRIEF DESCRIPTION OF THE DRAWINGS

FIG. 1 is a schematic diagram illustrating a generic system that enables the production of improved plasma products by using multiple simultaneous electrical discharges in accordance with the present invention.

FIG. 2 is a schematic diagram similar to that illustrated in FIG. 1 as it would be configured for a treatment option involving liquids.

FIG. 3 is a schematic diagram similar to that illustrated in FIG. 1 as it would be configured for a treatment option involving solids, both fine solids and conventional solids or processed solids.

FIG. 4 is a schematic diagram similar to that illustrated in FIG. 1 as it would be configured for a treatment option of gases.

FIG. 5 is a schematic diagram similar to that illustrated in FIG. 1 as it would be configured for a treatment option involving liquids having solids suspended in the liquid.

FIG. 6 is a schematic diagram showing normal cement water interactions.

FIG. 7 is a schematic diagram showing the impact of nanoparticles on cement structure in accordance with the present invention.

FIG. 8 is a graph illustrating the results of strength testing of cement cubes made from an improved plasma product in accordance with the present invention.

FIG. 9 is a schematic diagram illustrating the creation of an improved plasma product whereby the ability to control the plasma intensity and residual free radicals using on-line monitoring is done in conjunction with controlling changes in frequency, magnetic field and number of electrode elements used.

### DETAILED DESCRIPTION OF THE INVENTION

In addition to the constructions previously stated, the descriptions of the non-thermal improved plasma product variations presented herein are merely illustrative in nature and are in no way intended to limit the scope of the instant disclosure, product applications, or product uses. The description and examples are presented herein solely for the purpose of illustrating the various embodiments of the disclosure and should not be construed as a limitation to the scope and applicability of the disclosure. In the summary of the disclosure and this detailed description, each numerical value should be read once as modified by the term “about” (unless already expressly so modified), and then read again as not so modified unless otherwise indicated in context. Also, in the summary of the disclosure and this detailed description, it should be understood that a concentration or amount or value range listed or described as being useful, suitable, or the like, is intended that any and every concentration or amount or value within the range, including the end points, is to be considered as having been stated. For example, “a range of from 1 to 10” is to be read as indicating every possible number along the continuum between about 1 and about 10. Thus, even if specific data points within the range, or even no data points within the range, are explicitly identified or refer to only a few specific, it is to be understood that inventors appreciate and understand that any and all data points within the range are to be considered to have been specified, and that the inventors had possession of the entire range and all points within the range.

Unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of concepts according to the disclosure. This description should be read to include one or at least one and the singular also includes the plural unless otherwise stated.

It is to be understood that the term “product” or “products” as used in this application is “any substance, material or combination of materials that can exist in a solid, liquid or gaseous state”.

The terminology and phraseology used herein is for descriptive purposes and should not be construed as limiting in scope. Language such as “including,” “comprising,” “having,” “containing,” or “involving,” and variations thereof, is intended to be broad and encompass the subject matter listed thereafter, equivalents, and additional subject matter not recited.

Also, as used herein any references to “one embodiment” or “an embodiment” means that a particular element, feature, structure, or characteristic described in connection with the embodiment is included in at least one embodiment. The appearances of the phrase “in one embodiment” in various places in the specification are not necessarily referring to the same embodiment.

In one embodiment, the non-thermal improved plasma products and processes for producing same require the use of a plasma chamber that has a plurality of freely moving electrode segments as the electric discharge medium and the ability to produce multiple discharges at rates of a millisecond or smaller time intervals within a working area of the plasma chamber. The electrode segments are not “fixed” in a particular position or stationary. The electrode segments are moved within the plasma chamber substantially along a circular orbit by means of an external rotating electromagnetic field. Each freely moving electrode segment practically instantaneously attains an energy level that depends on motion speed of the electrode segments, the mass and size of the electrode segments, magnetic field intensity, exposition time, among other variables. In the present invention, these parameters are monitored so that they can be adjusted as desired or required for any particular improved plasma product. This aspect of the present invention will be discussed further in this detailed description.

In accordance with one embodiment, certain boundary “conditions” can be established to create a desired outcome. One such condition is that the fiber or particle lengths introduced to or inputted into to the chamber (i.e., the “input”) as passthrough material be less than the length of the electrode segments. Another condition would be to modify the surfaces of the electrode segments to provide reactive or catalytic surfaces. In another embodiment the use of longer fibers or particles in the passthrough material enables surface modifications without disruption of the particle length. Yet another condition could be to use smaller electrode segments to produce nanoparticles. The precise control of particle diameter yields new catalysts with high selectivity. Such catalysts can readily accelerate many chemical processes. In accordance with one embodiment, catalysts can be used in the plasma chamber and modifications of the electrode segments can be made such that the electrode segments are not only simple discharge agents but become catalytic or stimulant structures. Electrode segments in the simplest form could be comprised of magnetically soft iron-based materials. They could also be non-ferrous materials that are magnetically soft, such as those made of cobalt and nickel. In another embodiment, the electrode segments can be coated with materials that act as catalysts that do not adversely affect the magnetic properties of the electrode segments. Coating the electrode segments with any electrically conductive material prevents the introduction of iron into the improved plasma product so that iron and iron compounds are not present in the end product. Further, and by coating the electrode segments, the catalysts are retained within the reaction zone of the chamber. In another embodiment, non-magnetic catalysts can be introduced and then captured for recycling or reuse if they pass out of the reaction zone for one reason or another.

In accordance with embodiments disclosed herein, it should also be noted that there is a significant underlying principle of operation involving the role of oxygen and bubbles in plasma discharge reactions. The physical and chemical processes from a streaming plasma in liquid, such as water, can include: electrical discharge, electrons, ultraviolet radiation, pressure waves, free radicals, short timeframe high temperature regimes, ultrasonic effects and cavitation. It is further to be noted that the above-mentioned plasma discharge reactions can occur in gases, liquids, and solids and combinations of these with the gases being present in the liquid as bubbles (including macro-bubbles, micro-bubbles or nano-bubbles) dissolved or in a mixed phase of solids and gases; solids, liquids and gases; and liquids and gases. Plasma in a vapor bubble will generate similar species to a plasma over liquid. The reactive species generated in the bubble can diffuse across a plasma over liquid. The reactive species generated in the bubble can diffuse across the plasma-liquid interface and will enter the liquid when the bubble is broken, which frequently happens during operation and, as a result, the reducing efficiency should be relatively higher compared to the plasma over liquid as previously described.

As set forth above, the improved plasma products described herein are able to be maintained at a predetermined quality, rate, or level over a useful lifetime. An example of a useful lifetime is anywhere from several hours to days, and even weeks, in the case of plasma activated water. An example of a predetermined quality over a useful lifetime is the ability of the plasma activated water to sustain microbial destruction over that useful lifetime. An example of a predetermined rate or level over a useful lifetime is the effectively indefinite increased strength of plasma treated cements and cement powders. More specifically, compression increases are three-fold in certain constructs that utilize plasma treated cements and cement powders,

In the embodiments described in this application, the systems and methods described herein, and in particular the passing of product through the non-thermal plasma chamber described herein, result in the formation of an improved plasma product having properties that are superior to the same product that has not passed through the non-thermal plasma chamber. Examples of superior properties include a longer useful lifetime, an improved efficacy, an improved effectiveness, an improved potency, an improved corrosion resistance, an improved density, an improved hardness, an improved durability, an improved strength and/or improved flexibility. For example, a product that has passed through the non-thermal plasma chamber described herein will have a longer useful lifetime of hours, days or weeks as compared to that same product that has not passed through the non-thermal plasma chamber. As another example, a product that has passed through the non-thermal plasma chamber described herein will have an improved efficacy for milk production in bovine ruminants where production has been shown to increase up to 5% as compared to that same product that has not passed through the non-thermal plasma chamber. As another example, a product that has passed through the non-thermal plasma chamber described herein will show an improved effectiveness of reduction of microbial numbers between 70% and 80% as compared to that same product that has not passed through the non-thermal plasma chamber. As another example, a product that has passed through the non-thermal plasma chamber described herein will have an improved potency in the case of a biocidal kill rate over the useful lifetime in the case of plasma activated water as compared to that same product that has not passed through the non-thermal plasma chamber. As another example, a product that has passed through the non-thermal plasma chamber described herein will have an improved density in the case of plasma treated cements and cement powders as compared to that same products that have not passed through the non-thermal plasma chamber. As another example, a product that has passed through the non-thermal plasma chamber described herein will have an improved hardness, durability and strength of up to three times the normal amount pounds per square inch (psi), or Newtons per square millimeter (N/mm²) in the case of plasma treated cements and cement powders as compared to that same product that has not passed through the non-thermal plasma chamber under some common hardness testing methods including Rockwell, Brinell, and Vickers.

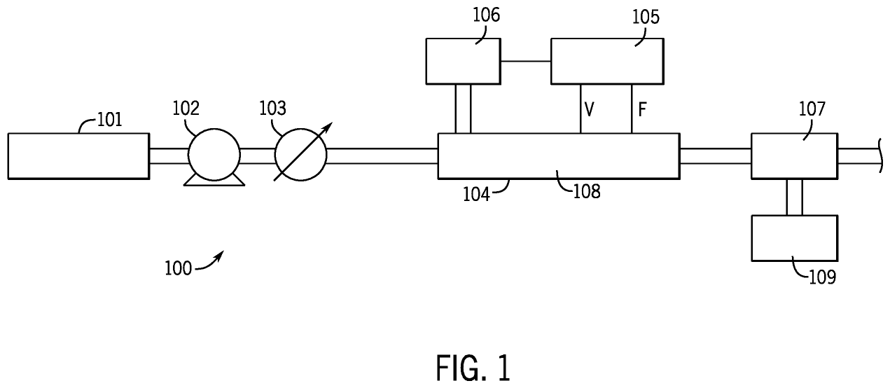

Referring now to the drawings, FIG. 1 illustrates a generic non-thermal system, generally identified 100, that is shown to be configured in accordance with the present invention. The system 100 comprises a preprocessing or storage unit 101 that contains the material (not shown) to be treated. Moving along the system 100 in much the same path as that of the material to be treated, the next downstream elements would be a feed pump 102 and a flow meter 103. It is to be understood that the feed pump 102 would include conventional elements to enable and allow for variable flow rates from the feed pump 102 depending on the material being treated. The flow meter 103 would likewise include conventional elements to measure and control the flow rate in real time. That is, the flow meter 103 controls and regulates the feed pump 102 as desired or required. The material would next flow downstream to a plasma chamber 104. This plasma chamber 104 would include a magnetic field generator and a magnetic field control, collectively element 108. Disposed within the magnetic field generator 108 is a plurality of electrode segments (not shown) that are fed into the plasma chamber 104 from an automatic feed 106 at a rate that is desired or required, depending on the material to be processed and on the type of electrode segments required for the intended process. The system 100 also includes a frequency and voltage control unit 105, in the form of a programmable logic controller (“PLC”) which effectively controls the plasma-generation process by controlling the interaction between the magnetic field and the electrode segments disposed within the plasma chamber 104, the latter being configured depending on the plasma reaction being used. As mentioned earlier, the control unit 105 can control the plasma intensity and residual free radicals using on-line monitoring in conjunction with the changes in the frequency, magnetic field and number and type of electrode segments. Lastly, the system 100 comprises a separation device 107 wherein any electrode segments flowing out of the plasma chamber 104 can be separated from the reagent and the reagent can be held within a discharge unit or outflowed to another device 109 as may be desired or required by the desired application. It is also within the scope of the present invention that the reaction within the plasma chamber 104 can be monitored and that the liner (not shown) disposed within the plasma chamber 104 can be made of a material (e.g., basalt or silica) that also acts as a catalyst during the formulation of the improved plasma product. It is also to be understood that, under some conditions, it may be advisable to heat the material to a higher temperature or even increase the pressure in the reaction zone to assist the reactions. But this is not done by the plasma. The additional heat facilitates the process, but non-thermal plasma is being used as the added heat does not affect the temperature of the improved plasma product.

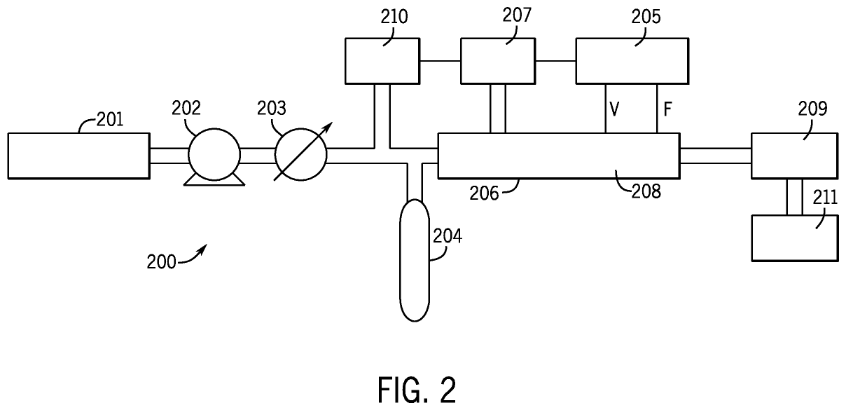

Referring now to FIG. 2, it illustrates a system, generally identified 200, that is also configured in accordance with the present invention. This particular system 200 is presented as an option for treating liquids. The system 200 comprises a preprocessing or storage unit 201 that contains the liquid (also not shown) to be treated. Moving along the system 200, the next downstream elements would be a feed pump 202 and a flow meter 203. It is to be understood that the feed pump 202 would include conventional elements to enable and allow for variable flow rates of liquid from the feed pump 202. The flow meter 203 would also include conventional elements to measure and control the flow rate of the liquid in real time. That is, the flow meter 203 controls and regulates the feed pump 202 as desired or required. The liquid would next flow downstream to a pH dosing unit 210 to achieve optimal pH adjustment and a gas input unit 204. The gas input could include oxygen as micro or nanobubbles, inert gases, ozone or mixtures of these. The frequency and voltage controller 205, the plasma chamber 206, the electrode segment feed 207 and magnetic field control 208 all function in the same way as described relative to the generic system 100. Included with the liquid treatment system 200, a post-processing unit 209 is provided to remove precipitates from the liquid plasma product output (not shown), filter the liquid plasma product, adjust pH values, and the like. The liquid plasma product is then held within a storage unit 211 or directed elsewhere for use.

It is to be noted here that the physical and chemical properties of the material may change during storage due to the presence of free radicals that are produced and stabilized in the process. The free radicals or their resultant active chemical moieties may persist for up to eighteen (18) months depending on the purity of the liquids contained in the storage unit and the chemical composition of the stored liquids, retaining some or all of their biocidal properties within that time frame.

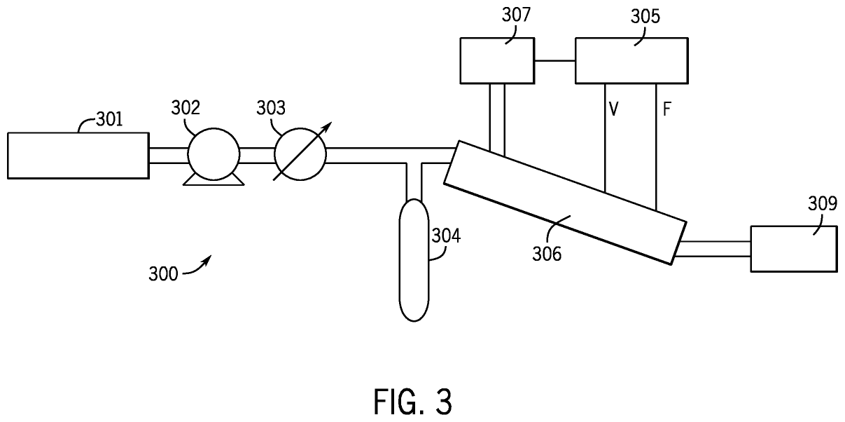

Referring now to FIG. 3, it illustrates a system, generally identified 300, that is also configured in accordance with the present invention. This particular system 300 is presented as an option for treating solids. The system 300 comprises a preprocessing or storage unit 301 that contains the solids (not shown) to be treated. The solids are fine solids, in the 50 μm to 500 μm range, and are suspended in air, gas or liquids, which may be acids, alkalis or other reagents. This system 300 likewise comprises a feed pump 302, a flow meter 303, and an input 304 for air, gases and reagents, all for much the same purposes as those mentioned relative to the systems 100 and 200. The system 300 also comprises a controller 305 and an electrode segment feed 307. The plasma chamber 306 is configured a bit differently in that it can be tilted, rotated, or tilted and rotated, to aid in the creation of the solid plasma product (not shown). In the example provided below, the plasma chamber 306 is tilted downwardly to aid in the flow of the improved plasma product through the system 300 and out of the plasma chamber 306. The solid plasma product is held within a hold 309 and can comprise conventional solids or processed solids. Examples of applications include the processing of cement powder, the extraction of valuable elements as metals, metal oxides or metal solutions.

### Specific Application of the Present Invention to Cement and Cement Powders

There are many methods for improving the strength and other properties of cements, concretes and mortars-whether they be the traditional “Portland cement” or the so-called “natural cements”. A brief overview is provided below.

### Portland Cement

As a preliminary matter, Portland cement is the generic term for the type of cement presently used in virtually all concrete. Portland cement, a form of hydraulic cement, is by far the most common type of cement in general use worldwide and is made by heating limestone (calcium carbonate) with other materials (such as clay) to 1,450° C. (2,640° F.) in a kiln. This is a process known as “calcination” that liberates a molecule of carbon dioxide from the calcium carbonate to form calcium oxide, or “quicklime”, which then chemically combines with the other materials in the mix to form calcium silicates and other cementitious compounds. The resulting hard substance, called “clinker”, is then ground with a small amount of gypsum into a powder to make ordinary Portland cement. The most common use for Portland cement is to make concrete, which is a composite material made of aggregate (gravel and sand), cement, and water. As a construction material, concrete can be cast in almost any shape, and, once it hardens, can be an extremely versatile structural (i.e., load bearing) material.

### Natural Cements

Unlike Portland cement, “natural cements” come from a single rock source with the right chemistry to produce hydraulic properties. Natural cements correspond to certain cements of the pre-Portland era and are produced by burning argillaceous limestones at moderate temperatures. The level of clay components in the limestone (around 30-35%) is such that large amounts of belite (the low-early strength, high-late strength mineral in Portland cement) are formed without the formation of excessive amounts of free lime. As with any natural material, such cements have highly variable properties.

Simply put, and for purposes of quick comparison, Portland cement (which is an artificial cement), is produced from a man-made mixture of pure limestone, silicates and clays that resemble the chemical composition of “marl” (which is a loose or crumbling earthy deposit that contains a substantial amount of calcium carbonate) or a variation of them in a controlled, reproducible manner. Natural cement connotes a raw material, i.e., a type of limestone (known as “clayey marl” which is a mixture of clay, sand, and limestone in varying proportions—it is soft and crumbly and usually contains shell fragments) is simply burnt with no other additions.

### Improving the Strength and Other Properties of Cements and Cement Powders

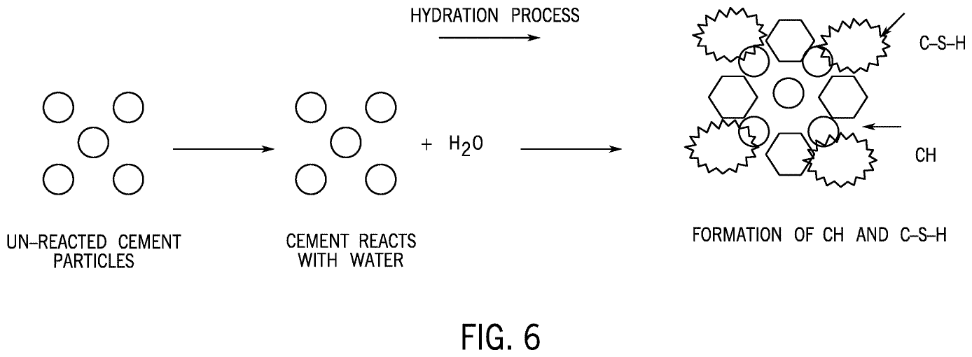

The most common ways for improving the strength and other properties of cements are to add inorganic solids such as clinker or slag to form geopolymers, organic polymers or materials that accelerate or slow the setting of the material or mixture. Today, one other method to improve the properties of cements, concrete and mortars include making the key materials smaller-so called nano-cements, or by incorporating very fine materials such as silica fume. The properties of this improved material as cements, concrete and mortars are attributed to the reduction in air spaces, improved reactions at a molecular level and more uniform reactions in the bulk materials. However, the preparation of nano-cements is time consuming, requiring large and expensive equipment such as ball mills or similar grinders and may require reprocessing of out-of-specification materials. Similarly, silica fume is used in specialized cements but is expensive and the cost, handling and processing to give a uniform mixture usually prevents its large-scale application to cements, concrete and mortars. These methods are claimed to improve the properties of the cements, concrete and mortars but also have disadvantages such to the variability of the composition of the added materials, the inconsistency of the resultant mixtures and the variations in particle size. Referring to FIG. 6, for example, it will be seen that, when unreacted cement particles react with water, a somewhat loose formation of calcium silicate hydrate (C-S-H) is created. The C—H-S is the main component of the hardened cement. It is effectively the glue phase of the cement, which is then dried.

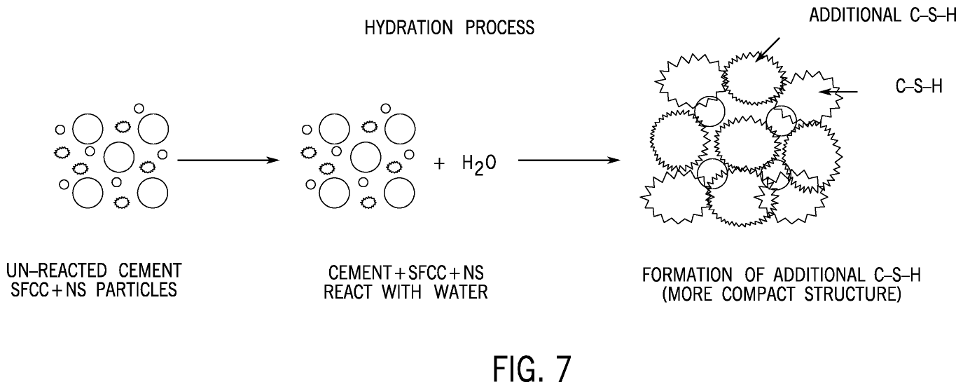

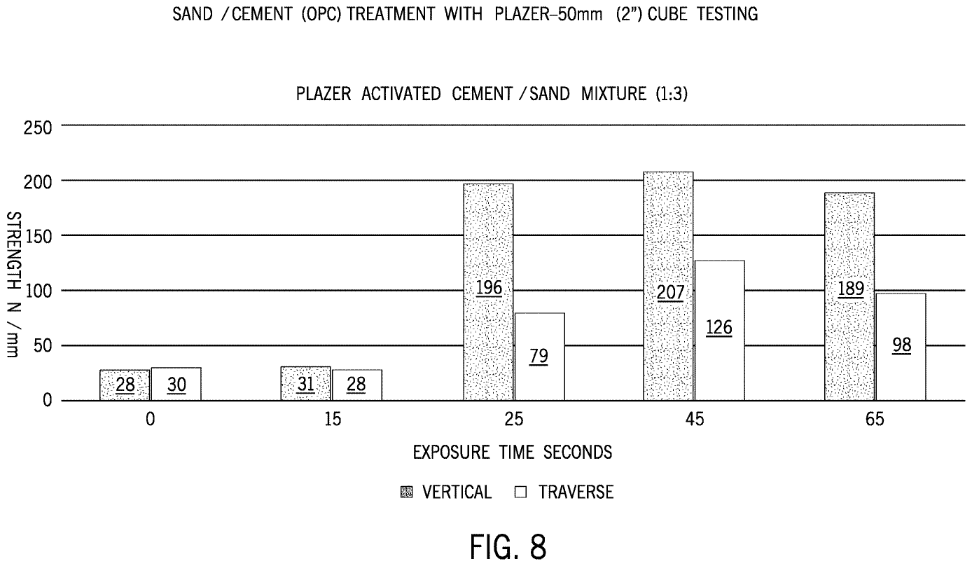

The use of plasma treated cement in accordance with the embodiments disclosed herein, with or without the presence of sand and other materials provides a novel method of improving the strength and other properties of cements, concrete and mortars without the disadvantages associated with other methods. In accordance with the process of the present invention, dry cements, concretes and mortars are passed through a non-thermal plasma and subjected to a micro-impulses and micro-arcs process. The impact of physical, chemical and electromagnetic effects on a plasma treated cement results in an activated material that has improved properties for all aspects and applications of cements, concretes and mortars. These processes result in the production of nanomaterials from small sized particles, provide size reduction of larger materials that are larger than about 0.5 mm, improved stability and reactivity of the key substrates of the active materials, cleaned and activated surfaces for materials that are in the mixture and activated forms of other materials including water that is free or bound that are present in the “dry” mixture. Referring to FIG. 7, for example, the impact of imparting nanoparticles into the unreacted cement particles which then reacts with water on hydration, creates a more compact structure. In this structure, C-S-H is created together with additional CSH. See FIG. 8.

This unique combination of processes leads to accelerated chemical and physical interactions with improved kinetics for the cement, concrete and mortar formation and setting processes. These can be both macro-duration and micro-duration. By referring to FIGS. 6 and 7, it can be appreciated that the outcome of these reactions is that complex solids are formed. The process also provides complete mixing of the materials which is not present in normal admixtures of the materials resulting in improved reactivity and interactions.

In accordance with the present invention, the material should be free flowing or “dry” for easy passage through the plasma reactor and generally would not contain more than 5% moisture, and preferably only 1% to 3% moisture. Provided the material flows freely through the reactor, the moisture content may be as high as 20%. The size of the materials other than the cements should be less than 2 mm. The cement should be less than 500 μm or preferably about 100 μm or smaller. Subsequent to the treatment of the cements, concretes and mortars, additional materials may be added including natural stone as aggregate, iron as bars or wires, organic or inorganic chemicals, silica, basalt and other organic or inorganic fibers. The water added may or may not have been treated by a non-thermal plasma process (i.e., plasma activated water). The addition of these materials in accordance with standard operating practice will result in the cements, concrete and mortars retaining their improved properties and will provide improved properties to the resultant materials. Regarding cements and cement powders, the improved properties of the resultant materials will include improved curing time to maximum strength, inherent strength with less cracking at the surface of the cured material or when the material is used in thin cross-sections, and improved water resistance. It should also be alluded to that plasma treatment or reaction is typically accomplished in less time thereby facilitating material production.

The novelty of the present invention further resides in the following reductions to practice:
1. The passage of dry cements, concrete and mortars through a non-thermal plasma process results in improved physical and chemical properties of the material when used as prescribed in standard operating procedures for the preparation of the material.
2. The treatment of the dry materials by this method results in increased strength of the materials after formulation by standard methods and as tested by standard testing methods that is at least 2 times stronger and up to 5 times stronger than equivalent untreated materials depending on the materials and the testing procedures.
3. The use of the non-thermal processed plasma material may enable a reduction in the amount of active material used in the final admixture or change the amounts of other additives that are used to enhance or change the properties of the cement, concrete or mortar.
4. The materials would contain no more than 5% moisture and preferably 1 to 3% moisture. Provided the material flows freely through the reactor, the moisture content may be as high as 20%.
5. The size of the materials other than the cements should be less than 2 mm. The cement should be less than 500 μm or preferably about 100 μm or smaller.
6. The use of plasma activated water activated using non-thermal plasma processing equipment is a preferred embodiment and enhances and improves the resultant materials.

One specific example relating to cement powder is provided immediately below and other examples follow.

### Example 1

The material was treated in a batch process at a capacity of 1.5 Liters. About 1 kg of standard cement was mixed with iron particles and exposed for periods from 10 to 80 seconds to assess the effects of exposure of the iron particles within the reactor. The cement was mixed with sand and water according to standard operating procedures and placed in holds for maturing at room temperature. The results indicate that an exposure of 20 secs. (after a warmup time of about 5 secs.) gave vertical and lateral compression increases by a factor of about three. Here is a summary of the results:

Samples were cut into approximately 2-inch blocks and tested vertically and transversely. The resulting values in psi were as follows:
Time 0. Vert. 400 Trans. 440
Time 15. Vert. 450. Trans. 400
Time 25. Vert. 2850 Trans. 1140
Time 45 Vert. 3000. Trans. 1830
Time 85. Vert. 2740. Trans. 1420

The results are approximate as the blocks were not exactly 2-inch cubes. The splits and/or failure points were inconsistent and the test defines a major fault as a failure (e.g., a side split). In some transverse test cases, there were minor side splits either from air or uneven pressure application. It is contemplated that the material will be processed in bulk. This may be as air-suspended particles in a downwardly sloping plasma chamber to aid with material removal. This may also be mixed with plasma activated water (i.e., electrically expanded water). These results appear to enhance strength, but are not conclusive and not formed from silica-based material that is broken down by a cone crusher or other aggregate-forming method.

As shown in FIG. 8, further testing of the compressive strength of nano cement concrete formed in accordance with the present invention is clear, as evidenced from the measured results obtained by these inventors. As a further result, such nano cements eliminate surface cracking and water penetration in the final and fully hardened concrete which provide other concrete performance parameters. Such nano cements are but one example of an improved plasma products.

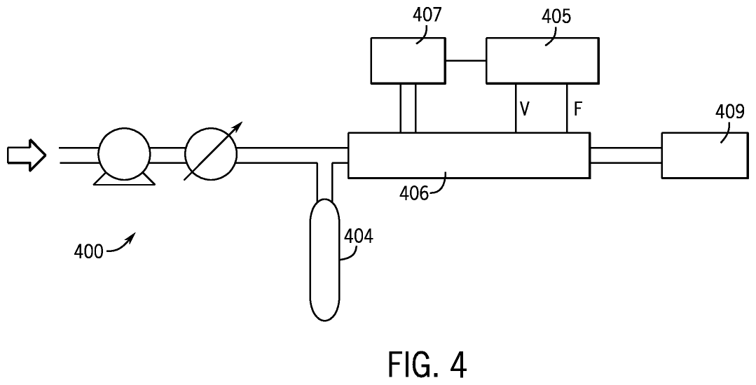

Referring now to FIG. 4, it illustrates a system, generally identified 400, that is also configured in accordance with the present invention. This particular system 400 is presented as an option for treating gases. At the front end of the system 400, gases can be inputted, also subject to flow control and metering as previously described. Significant in this example is the introduction of reagents 404, such as water, fine solids, reactive gases and other catalysts including titanium dioxide, also called titania (TiO₂), and cerium oxide (Ce₂O₆), a thermal catalyst, prior to the gas flowing into the plasma chamber 406, via the electrode segment feed 407. The controller 405 drives the plasma chamber 406 and the electrode segment feed 407. In this system 400, the electrode segments can be uncoated or coated with catalysts, the electrode segments (not shown) being inputted from the electrode segments feed 407. This system 400 may also be used for gas purification and solids separation in a post-processing unit 409.

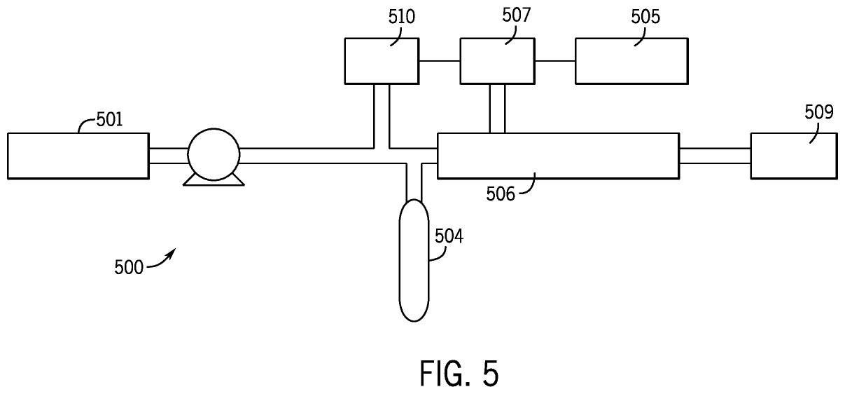

Referring now to FIG. 5, it illustrates a system, generally identified 500, that is also configured in accordance with the present invention. This system 500 is presented as an option for treating liquids with suspended solids and particles in them. The action of the plasma on the particles is to break them into smaller and smaller particles. Depending on the material, the effects are removal of surface material, fracturing of particles, and activation of surfaces without altering the underlying chemical properties. This system 500 includes a preprocessing unit 501. For particles to 5 mm or less, the system 500 can be used for size reduction or dissolution altogether. For particles 5 mm or more, the system 500 can be used for surface activation only. For particles less than 500 μm, the system 500 can be used for nanoparticle production, as discussed infra. The system 500 further includes elements 504, 505, 506, 507, 509, 510, which correspond to like structures in the other systems previously referred to.

### Example 2

In accordance with the present invention, the discharge of iron in a spark source creates iron free radicals, such as iron peroxidants, known as Fenton's Reagent, which is a long-lived reactive reagent. Fenton's Reagent is usually prepared in a solution of hydrogen peroxide (H₂O₂) with ferrous iron (typically iron (II) sulfate, FeSO₄) as a catalyst that is used to oxidize contaminants or waste waters as part of an advanced oxidation process. It is produced as part of the plasma discharges with iron electrode segments in the presence of oxygen or oxygen free radicals. Other long-lived reactive reagents can also be created. The formation of zero-valent iron—Fe⁰ in the plasma or other zero valent species is possible. Zero-valent iron is inexpensive, non-toxic and a moderate reducing reagent. In the presence of oxygen dissolved in water, zero-valent iron is capable of oxidizing organic pollutants. These react with organic matter, for example, with degradation of the organic matter, to produce simpler compounds depending on the reaction conditions. There are simulations of the reaction mechanisms in non-thermal plasmas that infer that over 700 different reactions may occur. For example, in the presence of oxidized nitrogen reactive and excited nitroso species may be formed in addition to the oxygen and hydrogen free radicals. That is, derivatives of organic hydrocarbons having one or more NO₂ groups bonded via nitrogen to the carbon framework (nitro compounds) or an NO group attached to carbon or nitrogen (nitroso compounds).

### Example 3

The table below references a sample of hematite that has been crushed to 500 μm and purified prior to treatment in a plasma unit. There are two treatment processes—the first is a single pass at “normal” operational flows and the second a slow pass with a 3-minute retention time. Powder sizes of Fe₂O₃ (after milling to 500-micron material) and treatment with a plasma unit (% composition of resultant powder).

| | Fractions % (microns) | | | | | | | | | | | | | |
|---|---|---|---|---|---|---|---|---|---|---|---|---|---|---|
| | 30-100 | 20-30 | 14-20 | 10-14 | 8-10 | 6-8 | 4.3-6 | 3-4.3 | 2-3 | 1.4-2.0 | 1-1.4 | 0.43-1 | 0.04-0.43 | Σ ≤ 1 |
| Single | 27.91 | 1.58 | 0.79 | 1.57 | 1.05 | 2.35 | 2.62 | 2.59 | 3.36 | 2.83 | 24.41 | 20.3 | 8.64 | 28.94 |
| pass from | | | | | | | | | | | | | | |
| 500 μm | | | | | | | | | | | | | | |

| | | | | | | | | | | | | |
|---|---|---|---|---|---|---|---|---|---|---|---|---|
| After | Not detected | 8.13 | 4.38 | 3.92 | 3.47 | 3.0 | 2.96 | 12.08 | 12.44 | 16.17 | 33.45 | 59.62 |
| Plasma | | | | | | | | | | | | |
| Treatment | | | | | | | | | | | | |
| 3 min. | | | | | | | | | | | | |

The above data indicates that the equipment can provide fine powders of less than 1 micron in a short time frame with a relatively small distribution of sizes. Multiple passes of materials can be used of either separated material or of the whole to achieve a nominated uniform small size distribution. Further processing or changes to the operating parameters to provide the sizes required for specific purposes are determined by experimentation.

### Specific Application of the Present Invention to Bovine Ruminants and Biosolids

On the manure side, these inventors have shown in small throughput operations (e.g., 7 m³/hour for 3 minutes) with a plasma treatment/exposure time of less than 2 seconds, the following results were obtained:

Reductions of microbial numbers by between 70% and 80%: (test by DNA from 1.8*10⁹ to 0.5*10⁹) for partly (no particle size reduction-just non-thermal plasma processing) and fully processed samples respectively:

| | |
|---|---|
| Prokarya | Reduction 81% |
| Eukarya | Reduction 77% |
| Hydrogen sulphide | Reduction 86% |
| bacteria | |
| Methanogens | Reduction 22% - this may be an artifact of the |
| | testing method but if it is not preservation of |
| | Methanogens is a good outcome. |

These results are best illustrated below:

This is the result of batch testing, where samples were transferred to tanks for a run of 7 m³/hour for 3 minutes. Further test results are illustrated as follows:

It is to be understood relative to the foregoing testing, that the following parameters and metrics applied:
Kingdom: Prokarya (Bacteria, Archaea), and Eukarya (Eukaryota, Fungi, Metazoa, Virdiplante)
Method: DNA amplicon sequencing of the 16S and 18S rRNA gene; qPCR quantitation of the 16S and 18S genes
Units: Prokarya—16S gene copies/mL; Eukarya—18S gene copies/mL

In what these inventors refer to as the “Biological Methane Potential” tests over 28 days the samples showed:
Improved biological methane potential short term and long term (14%)
Reduced H₂S production between 50 and 85%
   These results are illustrated below:

The product is thus more suitable for digester operation with a purer production of renewable natural gas. There are less-competing bacteria in the digester and the system resembles a pure feed optimized system. The rates of microbial kill are better than anything these inventors have ever seen reported in just a few seconds. Also, no other system has reported use for biosolids, making this a distinctive property of this embodiment. Specifically, and relative to biosolids, these inventors have shown that biosolids from wastewater from activated sludge plants-animal manure and paper waste processing plants—that are treated with plasma, settle quickly (within 30 minutes) to form dense thickened sludges more rapidly that normally take 10 to 15 hours or longer to achieve the same results.

Lastly, these inventors have shown that water that is treated by the non-thermal plasma processing equipment produces more milk in dairy cows that drink the water by at least a 3 to 5% increase.

### Nanotechnology

As alluded to previously, nanoparticles can be produced for additive-type manufacturing. Materials (such as agglomerates) that are introduced with a size of less than 500 μm will produce a mixture of nanoparticles with the majority of the particles less than 500 nanometers. These materials could include plastics or carbon with or without the presence of metals that produce a uniform well mixed material not easily achieved by other methods with these sized such that they can be subsequently used in manufacturing processes. The use of plastics with nanoparticles can result in the mixing of the material with metallic particles that can be used in additive manufacturing such as 3-D printing, for example.

Formation of novel nanoparticles is possible by direct interaction of solids and liquids using variations or similar chemical components that are in the prior art. However, and as evidenced above, the use of high temperatures, high pressures and extreme reaction conditions are not required under the present invention. The use of alternative and novel reaction mechanisms may be produced under the present invention. Note, for example, the following:
Gaseous reactions can include formation of syngas, removal of hydrogen sulfide, production of ammonia. Such reactions could include the presence of catalysts or scavenger materials that assist in the removal of interfering chemical species which results in the improved plasma product having superior properties;
Treatment of pharmaceuticals and their residues can be broken down to non-toxic chemicals and processing of the forever chemicals PFAS/PFOS can be undertaken and be assisted by the presence of calcium oxide or similar material with insoluble fluorides (supra page 5 of this disclosure) which results in the improved plasma product having superior properties;
Complex hydrocarbons can be broken down to more simple forms including lighter hydrocarbons and gases such as acetylene and methane and their homologues, or oxidized to water soluble species which results in the improved plasma product having superior properties;
In the presence of other gases, such as hydrogen, water and inert gases, complex unsaturated oils can become saturated or transformed to alcohols or ketones which results in the improved plasma product having superior properties;
Naturally occurring saturated or partially saturated oils can be made containing free radicals that assist with disinfection and wound healing which results in the improved plasma product having superior properties;
Dioxins or similar polyaromatic hydrocarbons can be broken down so that that they are suitable for safe disposal, reuse or low temperature incineration which results in the improved plasma product having superior properties;
Seeds that have been crushed for removal of oil can be treated further with the unit to give increased yields of oils that are similar to the quality of the first crushing and can have improved keeping or storage qualities which results in the improved plasma product having superior properties;
Improved germination of seeds using plasma has been demonstrated but this method of the present invention permits large scale controllable treatment of seed material suitable for using in agriculture, brewing and food processing which results in the improved plasma product having superior properties;
Under some conditions the preparation of flour or finely ground natural materials gives improved quality for all purposes and improved “keeping” qualities which results in the improved plasma product having superior properties;
The reactions also kill bacteria, fungi and viruses, which results in the improved plasma product having superior and which is supported by DNA tests by these inventors; the reactions can also work well in saline water which likewise produces saline water with no bacteria present, which results in the improved plasma product having superior properties;
The reactions can also have certain other direct impacts on saline water, including reductions in corrosion, scale build-up, and reducing or even eliminating other chemical treatment costs, which results in the improved plasma product having superior properties;
The reactions can enhance subsequent bioreactions (such as biomethane generation) by removal of competing organisms; this could be of use in the preparation of pharmaceuticals and any mechanisms using bioreactors which results in the improved plasma product having superior properties;
For processes such as those involving sewage treatment the material will be free of organisms that contain antibiotic resistance, and those can be removed or not generated which results in the improved plasma product having superior properties; and
The plasma can be used for non-thermal treatment of solids, liquids and gases to give microbially-free products (also referred to as “pasteurization”) which results in the improved plasma product having superior properties.
The improved plasma product may be the result of treating larger particles using electrode segments that are smaller, such that certain solids (e.g., cellulose fibers from wood or paper wastes or plant material such as hemp or bamboo, can become either nano cellulose fibers or activated cellulose fibers and be the precursors to activated carbon or graphene oxides; such cellulose cells being absorbent binding agents with biodegradable characteristics for environmental concerns;
The use of improved plasma products in accordance with the embodiments herein can also “jump start” certain processes, practices and procedures such that doing so significantly reduces pretreatment costs in those applications.

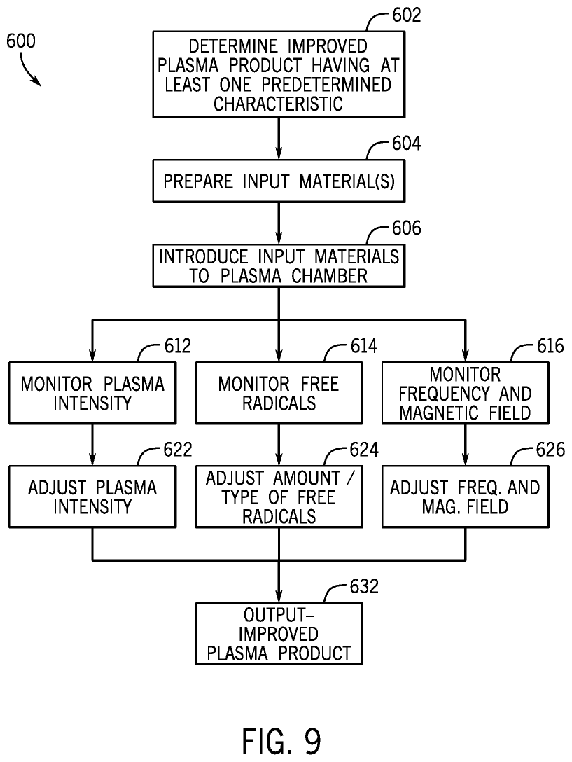

Each of the foregoing examples demonstrate that the use of multiple electrodes, or electrode segments, to form an improved plasma can result in a myriad of synergistic reactions resulting from such use and at the end of which an improved plasma product is produced, the improved plasma product having superior properties when compared to the same product not passing through the non-thermal plasma chamber described herein. They also demonstrate that electrode materials can be varied to catalyze the intended reaction. Further, electrode segment size and composition can also be varied to adjust for the desired, required or intended result or outcome. As alluded to previously, each freely moving electrode segment practically instantaneously attains an energy level that depends on motion speed of the electrode segments, the mass and size of the electrode segments, magnetic field intensity, exposition time, among other variables. In the present invention, these parameters are monitored so that they can be adjusted as desired or required for any particular improved plasma product. This is best illustrated in FIG. 9. In this regard, the process is generally identified 600. The user must first determine the type of improved plasma product to be made 602. Once that is determined, the input materials must be prepared 604 and then introduced 606 to the plasma chamber of the type previously described. Once the input materials are disposed within the reaction area of the plasma chamber, plasma intensity 612, free radicals 614 and frequency and magnetic field 616 can be monitored. If any one of the parameters needs to be varied to optimize the desired quality of the throughput material, the parameters can be adjusted 622, 624, 626. Once the throughput material has been suitably prepared, it can be outputted 632 as the improved plasma product desired or required.

In accordance with the present invention, iron electrode segments can also be done away with entirely. This changes the chemistry within the chamber such that the electrode segments can be anything that is a conducting soft magnetic material (i.e., the nickel cobalt mentioned above). By retaining the catalytic agent within the plasma chamber, iron particles remain attached to the electrode segments so that they are not washed out with the material flowing through the chamber, as previously described. The role of the magnetic field in sustaining the plasma and the free radicals is maintained.

It is also to be noted that cavitation and pressure waves are also present in plasmas formed by this method and depending on the operating conditions some localized temperature increases result from plasma interactions and product formation.

Lastly, the impacts of the process in accordance with the embodiments described herein demonstrate that materials used can be reduced in ranges from micron to nano levels, e.g., cement at 100 μm to ^{~}100 nm or less and sand at 2 mm to ^{~}100 μm or less. Surfaces are activated, which includes inorganics and organic materials. Reactions are completed via localized thermal heating and exposure to electrons. All of which enables large scale, cost effective, plasma reactive processing.

We claim:

1. A plasma product having at least one predetermined characteristic maintained over a useful lifetime obtained by the input of material comprising at least one of a solid, a liquid or a gas, or a combination thereof, feeding the input material into a non-thermal plasma chamber as a throughput material, the plasma product being the output of the throughput material and the output material comprising at least one of a solid, a liquid, a gas or a combination thereof, the output material comprising the plasma product and the plasma product having at least one property that is superior to the input material that has not passed through the non-thermal plasma chamber.

2. The plasma product of claim 1 comprising a reagent.

3. The plasma product of claim 1 further comprising the introduction of at least one catalyst.

4. The plasma product of claim 1 wherein the output of the throughput material is capable of indefinite operation such that product output is continuous.

5. The plasma product of claim 1 wherein the output material is at least one of a cement, a cement powder, a concrete or a mortar.

6. The plasma product of claim 1 wherein the output material is a nanomaterial.

7. A plasma product having at least one predetermined characteristic maintained over a useful lifetime comprising at least one of a solid, a liquid or a gas, or a combination thereof, produced by non-thermal conversion of at least another one of a solid, a liquid, a gas, or a combination thereof, to a plasma state wherein such non-thermal conversion results in the formation of and a throughput of the plasma product having at least one property that is superior to the at least another one of a solid, a liquid, a gas, or a combination thereof that has not passed through the non-thermal plasma chamber.

8. The plasma product of claim 7 comprising a reagent.

9. The plasma product of claim 7 further comprising the introduction of at least one catalyst.

10. The plasma product of claim 7 wherein non-thermal conversion of the at least another one of a solid, a liquid, a gas, or a combination thereof, to a plasma state is capable of indefinite operation such that product output is continuous.

11. The plasma product of claim 7 wherein the output material is at least one of a cement, a cement powder, a concrete or a mortar.

12. The plasma product of claim 7 wherein the output material is a nanomaterial.

13. A plasma product obtained by a process using a system, the system comprising:
a storage unit that contains an input material;
moving the input material from the storage unit using a variable flow rate feed;
using a flow meter to measure and control the variable flow rate feed;
providing a non-thermal plasma chamber into which the input material is fed, the plasma chamber including a magnetic field generator for generating a magnetic field and a magnetic field control;
feeding a plurality of electrode segments by an automatic feed into the plasma chamber wherein the electrode segments freely move in the plasma chamber during a reaction phase;
providing a frequency and voltage control unit in the form of a programmable logic controller that controls a conversion of the input material to a plasma in the reaction phase by controlling an interaction between the magnetic field and the electrode segments disposed within the plasma chamber;
moving the input material through the plasma chamber in the reaction phase as throughput material;
moving the throughput material to a discharge unit as output material;
holding the output material in the discharge unit;
wherein the output material comprises the plasma product.

14. The plasma product of claim 13 comprising a reagent.

15. The plasma product of claim 13 wherein moving the input material through the plasma chamber step further comprises the step of adding at least one catalyst wherein such catalyst is added via the plasma chamber, the electrode segments, or both.

16. The plasma product of claim 13 wherein conversion of the at least another one of a solid, a liquid, a gas, or a combination thereof, to a plasma state is capable of indefinite operation such that product throughput can be continuous.

17. The plasma product of claim 13 wherein the input material is a liquid.

18. The plasma product of claim 17 wherein the system further comprises a pH dosing unit and a gas input unit.

19. The plasma product of claim 17 wherein the gas input includes at least one of oxygen as micro or nanobubbles, inert gases, ozone, or mixtures thereof.

20. The plasma product of claim 13 wherein the input material is a solid.

21. The plasma product of claim 20 wherein the input material is a fine solid suspended in air, gas, or liquid.

22. The plasma product of claim 21 wherein the output material is at least one of a cement, a cement powder, a concrete or a mortar.

23. The plasma product of claim 13 wherein the output material is a nanomaterial.

24. The plasma product of claim 13 wherein the input material is a gas.

25. The plasma product of claim 13 wherein the input material is a liquid with suspended solid particles.

26. The plasma product of claim 13 wherein the frequency and voltage control unit of the system comprises on-line monitoring and controlling of changes in frequency, magnetic field and number of electrode segments which allows for control in plasma intensity and residual free radicals.

27. A system for generating a plasma product comprising:
a storage unit that contains an input material;
a non-thermal plasma chamber including a magnetic field generator for generating a magnetic field;
a feed pump to move the input material from the storage unit to the non-thermal plasma chamber;
a plurality of electrode segments that are fed into the plasma chamber by an automatic feed; wherein the electrode segments freely move in the plasma chamber during a reaction phase; and
a control unit that controls an interaction between the magnetic field and the plurality of electrode segments disposed within the plasma chamber.

28. A plasma product obtained by a process using a system, the system comprising:
a storage unit that contains an input material;
moving the input material from the storage unit using a feed pump;
using a flow meter to control the feed pump;
providing a non-thermal plasma chamber into which the input material is fed, the plasma chamber including a magnetic field generator for generating a magnetic field and a magnetic field control;
feeding a plurality of electrode segments by an automatic feed into the plasma chamber wherein the electrode segments freely move in the plasma chamber during a reaction phase;
providing a control unit in the form of a programmable controller that controls a conversion of the input material to a plasma in the reaction phase by controlling an interaction between the magnetic field and the electrode segments disposed within the plasma chamber;
moving the input material through the plasma chamber in the reaction phase as throughput material;
moving the throughput material to a discharge unit as output material;
holding the output material in the discharge unit;
wherein the output material comprises the plasma product.
